(19) United States
(12) Patent Application Publication
(10) Pub. No.: US 2018/0122932 A1
(43) Pub. Date: May 3, 2018

(54) THIN FILM TRANSISTOR, MANUFACTURING METHOD THEREOF, ARRAY SUBSTRATE AND DISPLAY DEVICE

(71) Applicant: BOE TECHNOLOGY GROUP CO., LTD., Beijing (CN)

(72) Inventor: Xiaming ZHU, Beijing (CN)

(73) Assignee: BOE TECHNOLOGY GROUP CO., LTD., Beijing (CN)

(21) Appl. No.: 15/795,941

(22) Filed: Oct. 27, 2017

(30) Foreign Application Priority Data
Oct. 27, 2016 (CN) 201610970462.5

(51) Int. Cl. H01L 29/786; H01L 21/70

(52) U.S. Cl. CPC H01L 29/786; H01L 2021/775; H01L 21/707

(57) ABSTRACT

The present disclosure provides a TFT, a manufacturing method thereof, an array substrate and a display device. The TFT includes an N-type metal oxide TFT and a P-type metal oxide TFT. The manufacturing method includes a step of forming an active layer of the N-type metal oxide TFT and an active layer of a P-type metal oxide TFT on a base substrate through a single patterning process.

This application claims priority to Chinese Patent Application No. 201610970462.5 filled on Oct. 27, 2016, which is incorporated herein by reference in its entirety.

### TECHNICAL FIELD

The present disclosure relates to the field of display technology, in particular to a thin film transistor (TFT), a manufacturing method thereof, an array substrate and a display device.

### BACKGROUND

In order to provide a display device with a super narrow bezel and reduce its manufacture cost, it is necessary to integrate a gate driving circuit and a source driving circuit into an array substrate, and at this time, a Complementary Metal Oxide Semiconductor (CMOS) TFT is applied.

Usually, for the CMOS TFT, a Low Temperature Polycrystalline Silicon (LTPS) is used to form a semiconductor layer. However, due to such disadvantages as complexity, poor controllability and poor uniformity, an LTPS process has not been applied to the large-size display device manufactured using a 6^{th}-generation production line or higher. In the case that the CMOS TFT is manufactured through a metal oxide semiconductor, it is necessary to form a P-type metal oxide pattern and an N-type metal oxide pattern, leading to an increase in the number of patterning process, and thereby leading to an increase in the manufacture cost and difficulty.

### SUMMARY

In one aspect, the present disclosure provides in some embodiments a method for manufacturing a complementary TFT. The complementary TFT includes an N-type metal oxide TFT and a P-type meal oxide TFT. The method includes a step of forming an active layer of the N-type metal oxide TFT and an active layer of the P-type metal oxide TFT on a base substrate through a single patterning process.

In a possible embodiment of the present disclosure, the step of forming the active layer of the N-type metal oxide TFT and the active layer of the P-type metal oxide TFT on the base substrate through a single patterning process includes: forming an N-type metal oxide layer on the base substrate; patterning the N-type metal oxide layer to form a first N-type metal oxide pattern and a second N-type metal oxide pattern, the first N-type metal oxide pattern being the active layer of the N-type metal oxide TFT and the second N-type metal oxide pattern being used to form the active layer of the P-type metal oxide TFT; and subjecting the second N-type metal oxide pattern to ion injection to transform the second N-type metal oxide pattern into the active layer of the P-type metal oxide TFT.

In a possible embodiment of the present disclosure, the step of forming the active layer of the N-type metal oxide TFT and the active layer of the P-type metal oxide TFT on the base substrate through a single patterning process includes: forming a P-type metal oxide layer on the base substrate; patterning the P-type metal oxide layer to form a first P-type metal oxide pattern and a second P-type metal oxide pattern, the first P-type metal oxide pattern being the active layer of the P-type metal oxide TFT and the second P-type metal oxide pattern being used to form the active layer of the N-type metal oxide TFT; and subjecting the second P-type metal oxide pattern to ion injection to transform the second P-type metal oxide pattern into the active layer of the N-type metal oxide TFT.

In a possible embodiment of the present disclosure, the step of forming the active layer of the N-type metal oxide TFT and the active layer of the P-type metal oxide TFT on the base substrate through a single patterning process comprises: forming a bipolar metal oxide layer on the base substrate; patterning the bipolar metal oxide layer to form a first metal oxide pattern and a second metal oxide pattern, the first metal oxide pattern being used to form the active layer of the N-type metal oxide TFT and the second metal oxide pattern being used to form the active layer of the P-type metal oxide TFT; subjecting the first metal oxide pattern to ion injection to transform the first metal oxide pattern into the active layer of the N-type metal oxide TFT; and subjecting the second metal oxide pattern to ion injection to transform the second metal oxide pattern into the active layer of the P-type metal oxide TFT.

In a possible embodiment of the present disclosure, prior to the step of forming the active layer of the N-type metal oxide TFT and the active layer of the P-type metal oxide TFT on the base substrate through a single patterning process, the method further includes forming a pattern of a first metal layer through a single patterning process, the pattern of the first metal layer including a pattern of a first electrode of the N-type metal oxide TFT and a pattern of a second electrode of the P-type metal oxide TFT. Subsequent to the step of forming the active layer of the N-type metal oxide TFT and the active layer of the P-type metal oxide TFT on the base substrate through a single patterning process, the method further includes forming a pattern of a second metal layer through a single patterning process, the pattern of the second metal layer including a pattern of a third electrode of the N-type metal oxide TFT and a pattern of a fourth pattern of the P-type metal oxide TFT. The first electrode and the second electrode are gate electrodes, and the third electrode and the fourth electrode each includes a source electrode and a drain electrode; or the third electrode and the fourth electrode are gate electrodes, and the first electrode and the second electrode each includes a source electrode and a drain electrode.

In a possible embodiment of the present disclosure, the active layer of the N-type metal oxide TFT is made of InGaZnO, InZnO, InSnZnO, SnO₂, In₂O₃, CuInO₂:Sn, ZnO or ZnON.

In a possible embodiment of the present disclosure, the active layer of the P-type metal oxide TFT is made of ZnCo₂O₄, CuInO₂:Ca, Cu₂O or SnO.

In another aspect, the present disclosure provides in some embodiments a complementary TFT manufactured by the above-mentioned method and including an N-type metal oxide TFT and a P-type metal oxide TFT.

In a possible embodiment of the present disclosure, the complementary TFT includes in turn: a pattern of a first metal layer including a pattern of a first electrode of the N-type metal oxide TFT and a pattern of a second electrode of the P-type metal oxide TFT; an active layer of the N-type metal oxide TFT and an active layer of the P-type metal oxide TFT; and a pattern of a second metal layer including a pattern of a third electrode of the N-type metal oxide TFT and a pattern of a fourth electrode of the P-type metal oxide TFT. The first electrode and the second electrode are gate electrodes, and the third electrode and the fourth electrode each includes a source electrode and a drain electrode; or the third electrode and the fourth electrode are gate electrodes, and the first electrode and the second electrode each includes a source electrode and a drain electrode.

In yet another aspect, the present disclosure provides in some embodiments an array substrate including the above-mentioned complementary TFT.

In a possible embodiment of the present disclosure, the array substrate includes in turn: a base substrate; a gate electrode of an N-type metal oxide TFT and a gate electrode of a P-type metal oxide TFT on the base substrate; a gate insulation layer; an active layer of the N-type metal oxide TFT and an active layer of the P-type metal oxide TFT on the gate insulation layer; a pattern of a first etch stop layer on the active layer of the N-type metal oxide TFT and a pattern of a second etch stop layer on the active layer of the P-type metal oxide TFT; a source electrode and a drain electrode of the N-type metal oxide TFT and a source electrode and a drain electrode of the P-type metal oxide TFT; and a passivation layer.

In a possible embodiment of the present disclosure, the array substrate includes in turn: a base substrate; an active layer of an N-type metal oxide TFT and an active layer of a P-type metal oxide TFT on the base substrate; a pattern of a first etch stop layer on the active layer of the N-type metal oxide TFT and a pattern of a second etch stop layer on the active layer of the P-type metal oxide TFT; a source electrode and a drain electrode of the N-type metal oxide TFT and a source electrode and a drain electrode of the P-type metal oxide TFT; a gate insulation layer; a gate electrode of the N-type metal oxide TFT and a gate electrode of the P-type metal oxide TFT on the gate insulation layer; and a passivation layer.

In a possible embodiment of the present disclosure, the source electrode and the drain electrode of the N-type metal oxide TFT and the source electrode and the drain electrode of the P-type metal oxide TFT are each made of Al and/or Mo.

In a possible embodiment of the present disclosure, the array substrate includes in turn: a base substrate; a gate electrode of an N-type metal oxide TFT and a gate electrode of a P-type metal oxide TFT on the base substrate; a gate insulation layer; an active layer of the N-type metal oxide TFT and an active layer of the P-type metal oxide TFT on the gate insulation layer; a source electrode and a drain electrode of the N-type metal oxide TFT and a source electrode and a drain electrode of the P-type metal oxide TFT; and a passivation layer.

In a possible embodiment of the present disclosure, the array substrate includes in turn: a base substrate; an active layer of an N-type metal oxide TFT and an active layer of a P-type metal oxide TFT on the base substrate; a source electrode and a drain electrode of the N-type metal oxide TFT and a source electrode and a drain electrode of the P-type metal oxide TFT; a gate insulation layer; a gate electrode of the N-type metal oxide TFT and a gate electrode of the P-type metal oxide TFT on the gate insulation layer; and a passivation layer.

In a possible embodiment of the present disclosure, the source electrode and the drain electrode of the N-type metal oxide TFT and the source electrode and the drain electrode of the P-type metal oxide TFT are each made of Cu.

In still yet another aspect, the present disclosure provides in some embodiments a display device including the above-mentioned array substrate.

### BRIEF DESCRIPTION OF THE DRAWINGS

FIG. 1 is a schematic view showing a complementary TFT according to one embodiment of the present disclosure;

FIG. 2 is another schematic view showing the complementary TFT according to one embodiment of the present disclosure;

FIG. 3 is yet another schematic view showing the complementary TFT according to one embodiment of the present disclosure; and

FIG. 4 is still yet another schematic view showing the complementary TFT according to one embodiment of the present disclosure.

### DETAILED DESCRIPTION

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “connect” or “connected to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

In the related art, a CMOS TFT is manufactured by a metal oxide semiconductor through a relatively large number of patterning processes. An object of the present disclosure is to provide a TFT, a manufacturing method thereof, an array substrate and a display device to reduce the number of the patterning processes for the CMOS TFT, thereby to reduce the manufacture cost and difficulty.

The present disclosure provides in some embodiments a method for manufacturing a complementary TFT. The complementary TFT includes an N-type metal oxide TFT and a P-type meal oxide TFT. The method includes a step of forming an active layer of the N-type metal oxide TFT and an active layer of the P-type metal oxide TFT on a base substrate through a single patterning process. The single patterning process is a process in which patterns are formed using one mask plate and through a single operation including one exposing step, one developing step and one etching step.

For the N-type metal oxide TFT, a semiconductor layer is made of an N-type oxide semiconductor material. The so-called N-type oxide semiconductor may be a reduction-type semiconductor whose conductivity increases along with a reducing atmosphere, and it may be made of InGaZnO, InZnO, InSnZnO, SnO₂, In₂O₃, CuInO₂:Sn, ZnO or ZnON. For the P-type metal oxide TFT, a semiconductor layer is made of a P-type oxide semiconductor material. The so-called P-type oxide semiconductor may be an oxidation-type semiconductor whose conductivity increases along with an oxidizing atmosphere, and it may be made of ZnCo₂O₄, CuInO₂:Ca, Cu₂O or SnO.

The complementary TFT with its semiconductor layers being made of the metal oxide has such advantages as excellent uniformity, high mobility and low power consumption, and thus may be applied to a large-size display device. In addition, it is compatible with an a-Si production device in a better manner, so it is able to further reduce the manufacture cost.

According to the method in the embodiments of the present disclosure, the active layers of the N-type metal oxide TFT and the P-type metal oxide TFT are formed on the base substrate through a single patterning process, rather than two patterning processes. As a result, it is able to reduce the number of patterning processes for the CMOS TFT and simplify the manufacture process thereof, thereby to reduce the manufacture cost for an array substrate.

During the implementation, a first N-type metal oxide pattern and a second N-type metal oxide pattern may be formed through a single patterning process using an N-type metal oxide layer. The step of forming the active layer of the N-type metal oxide TFT and the active layer of the P-type metal oxide TFT on the base substrate includes: forming an N-type metal oxide layer on the base substrate; patterning the N-type metal oxide layer to form the first N-type metal oxide pattern and the second N-type metal oxide pattern, the first N-type metal oxide pattern being the active layer of the N-type metal oxide TFT and the second N-type metal oxide pattern being used to form the active layer of the P-type metal oxide TFT; and subjecting the second N-type metal oxide pattern to ion injection to transform the second N-type metal oxide pattern into the active layer of the P-type metal oxide TFT. Here, ions for the ion injection may be for example, Ca, Co, Li, Na, K, Cu, N, P, As, or Sb. The to-be-injected ions may be accelerated in a vacuum and at a low temperature and then used to bombard a semiconductor material into which the ions are to be injected to enable the ions to directly enter the semiconductor material.

During the implementation, a first P-type metal oxide pattern and a second P-type metal oxide pattern may be formed through a single patterning process using a P-type metal oxide layer. The step of forming the active layer of the N-type metal oxide TFT and the active layer of the P-type metal oxide TFT on the base substrate through a single patterning process includes: forming a P-type metal oxide layer on the base substrate; patterning the P-type metal oxide layer to form the first P-type metal oxide pattern and the second P-type metal oxide pattern, the first P-type metal oxide pattern being the active layer of the P-type metal oxide TFT and the second P-type metal oxide pattern being used to form the active layer of the N-type metal oxide TFT; and subjecting the second P-type metal oxide pattern to ion injection to transform the second P-type metal oxide pattern into the active layer of the N-type metal oxide TFT. Here, ions for the ion injection may be for example, O, In, Zn, Sn, B, Al, Ga, F or H. The to-be-injected ions may be accelerated in a vacuum and at a low temperature and then used to bombard a semiconductor material into which the ions are to be injected to enable the ions to directly enter the semiconductor material.

In a possible embodiment of the present disclosure, the step of forming the active layer of the N-type metal oxide TFT and the active layer of the P-type metal oxide TFT on the base substrate through a single patterning process comprises: forming a bipolar metal oxide layer on the base substrate; patterning the bipolar metal oxide layer to form a first metal oxide pattern and a second metal oxide pattern, the first metal oxide pattern being used to form the active layer of the N-type metal oxide TFT and the second metal oxide pattern being used to form the active layer of the P-type metal oxide TFT; subjecting the first metal oxide pattern to ion injection to transform the first metal oxide pattern into the active layer of the N-type metal oxide TFT, wherein the ions for the ion injection may be O, In, Zn or Sn; and subjecting the second metal oxide pattern to ion injection to transform the second metal oxide pattern into the active layer of the P-type metal oxide TFT, wherein the ions for the ion injection may be Ca, N, Co, Li, Na, K, Cu, P, As or Sb.

In a possible embodiment of the present disclosure, prior to the step of forming the active layer of the N-type metal oxide TFT and the active layer of the P-type metal oxide TFT on the base substrate through a single patterning process, the method further includes forming a pattern of a first metal layer through a single patterning process, the pattern of the first metal layer including a pattern of a first electrode of the N-type metal oxide TFT and a pattern of a second electrode of the P-type metal oxide TFT. Subsequent to the step of forming the active layer of the N-type metal oxide TFT and the active layer of the P-type metal oxide TFT on the base substrate through a single patterning process, the method further includes forming a pattern of a second metal layer through a single patterning process, the pattern of the second metal layer including a pattern of a third electrode of the N-type metal oxide TFT and a pattern of a fourth pattern of the P-type metal oxide TFT. One of the first electrode and the third electrode is a gate electrode and the other includes a source electrode and a drain electrode, and one of the second electrode and the fourth electrode is a gate electrode and the other includes a source electrode and a drain electrode.

In a possible embodiment of the present disclosure, the active layer of the N-type metal oxide TFT is made of InGaZnO, InZnO, InSnZnO, SnO₂, In₂O₃, CuInO₂:Sn, ZnO or ZnON.

In a possible embodiment of the present disclosure, the active layer of the P-type metal oxide TFT is made of ZnCo₂O₄, CuInO₂:Ca, Cu₂O or SnO.

The present disclosure further provides in some embodiments a complementary TFT manufactured by the above-mentioned method and including an N-type metal oxide TFT and a P-type metal oxide TFT.

According to the complementary TFT in the embodiments of the present disclosure, the active layers of the N-type metal oxide TFT and the P-type metal oxide TFT are formed on the base substrate through a single patterning process, rather than two patterning processes. As a result, it is able to reduce the number of patterning processes for the CMOS TFT and simplify the manufacture process thereof, thereby to reduce the manufacture cost for an array substrate.

In a possible embodiment of the present disclosure, the complementary TFT includes: a pattern of a first metal layer including a pattern of a first electrode of the N-type metal oxide TFT and a pattern of a second electrode of the P-type metal oxide TFT; an active layer of the N-type metal oxide TFT and an active layer of the P-type metal oxide TFT arranged on the pattern of the first metal layer; and a pattern of a second metal layer including a pattern of a third electrode of the N-type metal oxide TFT and a pattern of a fourth electrode of the P-type metal oxide TFT. One of the first electrode and the third electrode is a gate electrode, and the other includes a source electrode and a drain electrode. One of the second electrode and the fourth electrode is a gate electrode, and the other includes a source electrode and a drain electrode.

The present disclosure further provides in some embodiments an array substrate including the above-mentioned complementary TFT and a pixel electrode.

In a possible embodiment of the present disclosure, the array substrate of a bottom-gate etch-stop type may include in turn: a base substrate; a gate electrode of an N-type metal oxide TFT and a gate electrode of a P-type metal oxide TFT on the base substrate; a gate insulation layer; an active layer of the N-type metal oxide TFT and an active layer of the P-type metal oxide TFT on the gate insulation layer; a pattern of a first etch stop layer on the active layer of the N-type metal oxide TFT and a pattern of a second etch stop layer on the active layer of the P-type metal oxide TFT; a source electrode and a drain electrode of the N-type metal oxide TFT and a source electrode and a drain electrode of the P-type metal oxide TFT; and a passivation layer.

In a possible embodiment of the present disclosure, the array substrate of a top-gate etch-stop type may include in turn: a base substrate; an active layer of an N-type metal oxide TFT and an active layer of a P-type metal oxide TFT on the base substrate; a pattern of a first etch stop layer on the active layer of the N-type metal oxide TFT and a pattern of a second etch stop layer on the active layer of the P-type metal oxide TFT; a source electrode and a drain electrode of the N-type metal oxide TFT and a source electrode and a drain electrode of the P-type metal oxide TFT; a gate insulation layer; a gate electrode of the N-type metal oxide TFT and a gate electrode of the P-type metal oxide TFT on the gate insulation layer; and a passivation layer.

In a possible embodiment of the present disclosure, for the array substrate of an etch-stop type, the source electrode and the drain electrode of the N-type metal oxide TFT and the source electrode and the drain electrode of the P-type metal oxide TFT are each made of Al and/or Mo.

In a possible embodiment of the present disclosure, the array substrate of a bottom-gate back-channel-etch type may include in turn: a base substrate; a gate electrode of an N-type metal oxide TFT and a gate electrode of a P-type metal oxide TFT on the base substrate; a gate insulation layer; an active layer of the N-type metal oxide TFT and an active layer of the P-type metal oxide TFT on the gate insulation layer; a source electrode and a drain electrode of the N-type metal oxide TFT and a source electrode and a drain electrode of the P-type metal oxide TFT; and a passivation layer.

In a possible embodiment of the present disclosure, the array substrate of a top-gate back-channel-etch type may include in turn: a base substrate; an active layer of an N-type metal oxide TFT and an active layer of a P-type metal oxide TFT on the base substrate; a source electrode and a drain electrode of the N-type metal oxide TFT and a source electrode and a drain electrode of the P-type metal oxide TFT; a gate insulation layer; a gate electrode of the N-type metal oxide TFT and a gate electrode of the P-type metal oxide TFT on the gate insulation layer; and a passivation layer.

In a possible embodiment of the present disclosure, for the array substrate of a back-channel-etch type, the source electrode and the drain electrode of the N-type metal oxide TFT and the source electrode and the drain electrode of the P-type metal oxide TFT are each made of Cu.

The present disclosure further provides in some embodiments a display device including the above-mentioned array substrate. The display device may be any product or member having a display function, such as a liquid crystal television, a liquid crystal display, a digital photo frame, a mobile phone or a flat-panel computer. The display device further includes a flexible circuit board, a printed circuit board and a back plate.

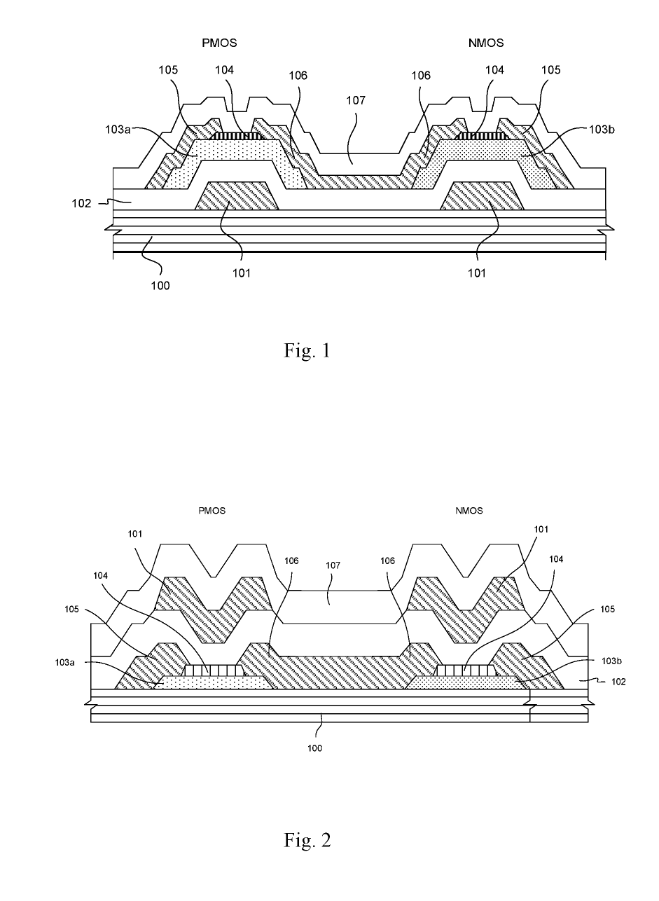

As shown in FIG. 1, the method for manufacturing the complementary TFT may include the following steps.

Step 1: providing a base substrate 100. To be specific, the base substrate 100 may be a glass substrate or a quartz substrate.

Step 2: depositing a first metal layer onto the base substrate 100, and patterning the first metal layer to form a gate electrode 101 of the N-type metal oxide TFT and a gate electrode 101 of the P-type metal oxide TFT. The first metal layer may be made of Al and/or Mo.

Step 3: forming a gate insulation layer 102 on the base substrate 100 acquired after Step 2.

Step 4: depositing an N-type metal oxide layer onto the gate insulation layer 102, patterning the N-type metal oxide layer to form a first N-type metal oxide pattern which is an active layer 103b of the N-type metal oxide TFT and a second N-type metal oxide pattern which is used to form an active layer 103a of the P-type metal oxide TFT, and subjecting the second N-type metal oxide pattern to ion injection and ion diffusion to transform the second N-type metal oxide pattern into the active layer 103a of the P-type metal oxide TFT.

In a possible embodiment of the present disclosure, Step 4 may also include: depositing a P-type metal oxide layer onto the gate insulation layer 102, patterning the P-type metal oxide layer to form a first P-type metal oxide pattern which is the active layer 103a of the P-type metal oxide TFT and a second P-type metal oxide pattern which is used to form the active layer 103b of the N-type metal oxide TFT, and subjecting the second P-type metal oxide pattern to ion injection and ion diffusion to transform the second P-type metal oxide pattern into the active layer 103b of the N-type metal oxide TFT.

Step 5: depositing a first insulation layer onto the base substrate 100 acquired after Step 4, and patterning the first insulation layer to form a pattern of an etch stop layer 104.

Step 6: depositing a second metal layer onto the base substrate acquired after Step 5, and patterning the second metal layer to form a source electrode 105 and a drain electrode 106 of the N-type metal oxide TFT and a source electrode 105 and a drain electrode 106 of the P-type metal oxide TFT. The second metal layer may be made of Al and/or Mo. The active layers 103a and 103b may be damaged by an etchant for etching the second metal layer, so it is necessary to provide the etch stop layer 104.

Step 7: forming a passivation layer 107 on the base substrate acquired after Step 6.

The array substrate in FIG. 1 may be acquired through the above Steps 1 to 7. According to the method in the embodiments of the present disclosure, the active layers of the N-type metal oxide TFT and the P-type metal oxide TFT are formed on the base substrate through a single patterning process, rather than two patterning processes. As a result, it is able to reduce the number of patterning processes for the CMOS TFT and simplify the manufacture process thereof, thereby to reduce the manufacture cost for the array substrate.

As shown in FIG. 2, the method for manufacturing the complementary TFT may include the following steps.

Step 1: providing a base substrate 100. To be specific, the base substrate 100 may be a glass substrate or a quartz substrate.

Step 2: depositing an N-type metal oxide layer onto the base substrate 100, patterning the N-type metal oxide layer to form a first N-type metal oxide pattern which is an active layer 103b of the N-type metal oxide TFT and a second N-type metal oxide pattern which is used to form an active layer 103a of the P-type metal oxide TFT, and subjecting the second N-type metal oxide pattern to ion injection and ion diffusion to transform the second N-type metal oxide pattern into the active layer 103a of the P-type metal oxide TFT.

In a possible embodiment of the present disclosure, Step 2 may also include: depositing a P-type metal oxide layer onto the gate insulation layer 102, patterning the P-type metal oxide layer to form a first P-type metal oxide pattern which is the active layer 103a of the P-type metal oxide TFT and a second P-type metal oxide pattern which is used to form the active layer 103b of the N-type metal oxide TFT, and subjecting the second P-type metal oxide pattern to ion injection and ion diffusion to transform the second P-type metal oxide pattern into the active layer 103b of the N-type metal oxide TFT.

Step 3: depositing a first insulation layer onto the base substrate 100 acquired after Step 2, and patterning the first insulation layer to form a pattern of an etch stop layer 104.

Step 4: depositing a first metal layer onto the base substrate 100 acquired after Step 3, and patterning the first metal layer to form a source electrode 105 and a drain electrode 106 of the N-type metal oxide TFT and a source electrode 105 and a drain electrode 106 of the P-type metal oxide TFT. The first metal layer may be made of Al and/or Mo. The active layers 103a and 103b may be damaged by an etchant for etching the first metal layer, so it is necessary to provide the etch stop layer 104.

Step 5: forming a gate insulation layer 102 on the base substrate 100 acquired after Step 4.

Step 6: depositing a second metal layer onto the gate insulation layer 102, and patterning the second metal layer to form a gate electrode 101 of the N-type metal oxide TFT and a gate electrode 101 of the P-type metal oxide TFT. The second metal layer may be made of Al and/or Mo.

Step 7: forming a passivation layer 107 on the base substrate acquired after Step 6.

The array substrate in FIG. 2 may be acquired through the above Steps 1 to 7. According to the method in the embodiments of the present disclosure, the active layers of the N-type metal oxide TFT and the P-type metal oxide TFT are formed on the base substrate through a single patterning process, rather than two patterning processes. As a result, it is able to reduce the number of patterning processes for the CMOS TFT and simplify the manufacture process thereof, thereby to reduce the manufacture cost for the array substrate.

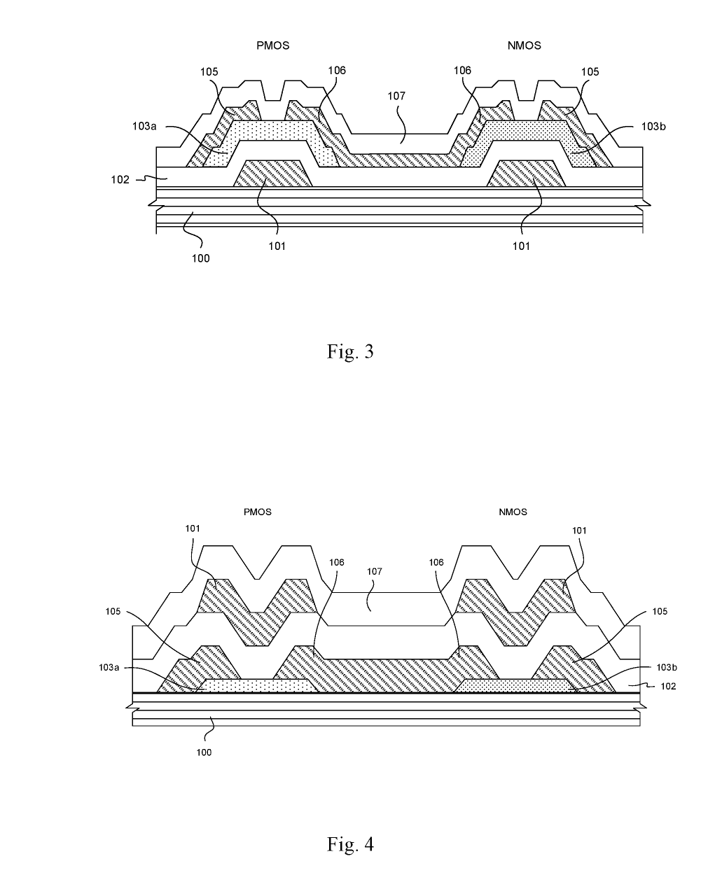

As shown in FIG. 3, the method for manufacturing the complementary TFT may include the following steps.

Step 1: providing a base substrate 100. To be specific, the base substrate 100 may be a glass substrate or a quartz substrate.

Step 2: depositing a first metal layer onto the base substrate 100, and patterning the first metal layer to form a gate electrode 101 of the N-type metal oxide TFT and a gate electrode 101 of the P-type metal oxide TFT. The first metal layer may be made of Cu.

Step 3: forming a gate insulation layer 102 on the base substrate 100 acquired after Step 2.

Step 4: depositing an N-type metal oxide layer onto the gate insulation layer 102, patterning the N-type metal oxide layer to form a first N-type metal oxide pattern which is an active layer 103b of the N-type metal oxide TFT and a second N-type metal oxide pattern which is used to form an active layer 103a of the P-type metal oxide TFT, and subjecting the second N-type metal oxide pattern to ion injection and ion diffusion to transform the second N-type metal oxide pattern into the active layer 103a of the P-type metal oxide TFT.

In a possible embodiment of the present disclosure, Step 4 may also include: depositing a P-type metal oxide layer onto the gate insulation layer 102, patterning the P-type metal oxide layer to form a first P-type metal oxide pattern which is the active layer 103a of the P-type metal oxide TFT and a second P-type metal oxide pattern which is used to form the active layer 103b of the N-type metal oxide TFT, and subjecting the second P-type metal oxide pattern to ion injection and ion diffusion to transform the second P-type metal oxide pattern into the active layer 103b of the N-type metal oxide TFT.

Step 5: depositing a second metal layer onto the base substrate acquired after Step 4, and patterning the second metal layer to form a source electrode 105 and a drain electrode 106 of the N-type metal oxide TFT and a source electrode 105 and a drain electrode 106 of the P-type metal oxide TFT. The second metal layer may be made of Cu. The active layers 103a and 103b may be not damaged by an etchant for etching the second metal layer, so it is unnecessary to provide any etch stop layer.

Step 6: forming a passivation layer 107 on the base substrate acquired after Step 5.

The array substrate in FIG. 1 may be acquired through the above Steps 1 to 6. According to the method in the embodiments of the present disclosure, the active layers of the N-type metal oxide TFT and the P-type metal oxide TFT are formed on the base substrate through a single patterning process, rather than two patterning processes. As a result, it is able to reduce the number of patterning processes for the CMOS TFT and simplify the manufacture process thereof, thereby to reduce the manufacture cost for the array substrate.

As shown in FIG. 4, the method for manufacturing the complementary TFT may include the following steps.

Step 1: providing a base substrate 100. To be specific, the base substrate 100 may be a glass substrate or a quartz substrate.

Step 2: depositing an N-type metal oxide layer onto the base substrate 100, patterning the N-type metal oxide layer to form a first N-type metal oxide pattern which is an active layer 103b of the N-type metal oxide TFT and a second N-type metal oxide pattern which is used to form an active layer 103a of the P-type metal oxide TFT, and subjecting the second N-type metal oxide pattern to ion injection and ion diffusion to transform the second N-type metal oxide pattern into the active layer 103a of the P-type metal oxide TFT.

In a possible embodiment of the present disclosure, Step 2 may also include: depositing a P-type metal oxide layer onto the gate insulation layer 102, patterning the P-type metal oxide layer to form a first P-type metal oxide pattern which is the active layer 103a of the P-type metal oxide TFT and a second P-type metal oxide pattern which is used to form the active layer 103b of the N-type metal oxide TFT, and subjecting the second P-type metal oxide pattern to ion injection and ion diffusion to transform the second P-type metal oxide pattern into the active layer 103b of the N-type metal oxide TFT.

Step 3: depositing a first metal layer onto the base substrate 100 acquired after Step 2, and patterning the first metal layer to form a source electrode 105 and a drain electrode 106 of the N-type metal oxide TFT and a source electrode 105 and a drain electrode 106 of the P-type metal oxide TFT. The first metal layer may be made of Cu. The active layers 103a and 103b may not be damaged by an etchant for etching the first metal layer, so it is unnecessary to provide any etch stop layer.

Step 5: forming a gate insulation layer 102 on the base substrate 100 acquired after Step 3.

Step 6: depositing a second metal layer onto the gate insulation layer 102, and patterning the second metal layer to form a gate electrode 101 of the N-type metal oxide TFT and a gate electrode 101 of the P-type metal oxide TFT. The second metal layer may be made of Cu.

Step 6: forming a passivation layer 107 on the base substrate acquired after Step 5.

The array substrate in FIG. 2 may be acquired through the above Steps 1 to 6. According to the method in the embodiments of the present disclosure, the active layers of the N-type metal oxide TFT and the P-type metal oxide TFT are formed on the base substrate through a single patterning process, rather than two patterning processes. As a result, it is able to reduce the number of patterning processes for the CMOS TFT and simplify the manufacture process thereof, thereby to reduce the manufacture cost for the array substrate.

The above are merely the preferred embodiments of the present disclosure, but the present disclosure is not limited thereto. Obviously, a person skilled in the art may make further modifications and improvements without departing from the spirit of the present disclosure, and these modifications and improvements shall also fall within the scope of the present disclosure.

What is claimed is:

1. A method for manufacturing a complementary thin film transistor (TFT), the complementary TFT comprising an N-type metal oxide TFT and a P-type meal oxide TFT, wherein the method comprises a step of forming an active layer of the N-type metal oxide TFT and an active layer of the P-type metal oxide TFT on a base substrate through a single patterning process.

2. The method according to claim 1, wherein the step of forming the active layer of the N-type metal oxide TFT and the active layer of the P-type metal oxide TFT on the base substrate through a single patterning process comprises:
forming an N-type metal oxide layer on the base substrate;
patterning the N-type metal oxide layer to form a first N-type metal oxide pattern and a second N-type metal oxide pattern, the first N-type metal oxide pattern being the active layer of the N-type metal oxide TFT and the second N-type metal oxide pattern being used to form the active layer of the P-type metal oxide TFT; and
subjecting the second N-type metal oxide pattern to ion injection to transform the second N-type metal oxide pattern into the active layer of the P-type metal oxide TFT.

3. The method according to claim 1, wherein the step of forming the active layer of the N-type metal oxide TFT and the active layer of the P-type metal oxide TFT on the base substrate through a single patterning process comprises:
forming a P-type metal oxide layer on the base substrate;
patterning the P-type metal oxide layer to form a first P-type metal oxide pattern and a second P-type metal oxide pattern, the first P-type metal oxide pattern being the active layer of the P-type metal oxide TFT and the second P-type metal oxide pattern being used to form the active layer of the N-type metal oxide TFT; and
subjecting the second P-type metal oxide pattern to ion injection to transform the second P-type metal oxide pattern into the active layer of the N-type metal oxide TFT.

4. The method according to claim 1, wherein the step of forming the active layer of the N-type metal oxide TFT and the active layer of the P-type metal oxide TFT on the base substrate through a single patterning process comprises:
forming a bipolar metal oxide layer on the base substrate;
patterning the bipolar metal oxide layer to form a first metal oxide pattern and a second metal oxide pattern, the first metal oxide pattern being used to form the active layer of the N-type metal oxide TFT and the second metal oxide pattern being used to form the active layer of the P-type metal oxide TFT;
subjecting the first metal oxide pattern to ion injection to transform the first metal oxide pattern into the active layer of the N-type metal oxide TFT; and
subjecting the second metal oxide pattern to ion injection to transform the second metal oxide pattern into the active layer of the P-type metal oxide TFT.

5. The method according to claim 1, wherein prior to the step of forming the active layer of the N-type metal oxide TFT and the active layer of the P-type metal oxide TFT on the base substrate through a single patterning process, the method further comprises forming a pattern of a first metal layer through a single patterning process, the pattern of the first metal layer including a pattern of a first electrode of the N-type metal oxide TFT and a pattern of a second electrode of the P-type metal oxide TFT;
subsequent to the step of forming the active layer of the N-type metal oxide TFT and the active layer of the P-type metal oxide TFT on the base substrate through a single patterning process, the method further comprise forming a pattern of a second metal layer through a single patterning process, the pattern of the second metal layer including a pattern of a third electrode of the N-type metal oxide TFT and a pattern of a fourth electrode of the P-type metal oxide TFT; and
the first electrode and the second electrode are gate electrodes, and the third electrode and the fourth electrode each includes a source electrode and a drain electrode; or the third electrode and the fourth electrode are gate electrodes, and the first electrode and the second electrode each includes a source electrode and a drain electrode.

6. The method according to claim 2, wherein the active layer of the N-type metal oxide TFT is made of InGaZnO, InZnO, InSnZnO, SnO₂, In₂O₃, CuInO₂:Sn, ZnO or ZnON.

7. The method according to claim 3, wherein the active layer of the P-type metal oxide TFT is made of ZnCo₂O₄, CuInO₂:Ca, Cu₂O or SnO.

8. A complementary thin film transistor (TFT), comprising an N-type metal oxide TFT and a P-type metal oxide TFT, wherein the complementary TFT further comprises in turn:
a pattern of a first metal layer comprising a pattern of a first electrode of the N-type metal oxide TFT and a pattern of a second electrode of the P-type metal oxide TFT;
an active layer of the N-type metal oxide TFT and an active layer of the P-type metal oxide TFT; and
a pattern of a second metal layer comprising a pattern of a third electrode of the N-type metal oxide TFT and a pattern of a fourth electrode of the P-type metal oxide TFT,
wherein the first electrode and the second electrode are gate electrodes, and the third electrode and the fourth electrode each includes a source electrode and a drain electrode; or the third electrode and the fourth electrode are gate electrodes, and the first electrode and the second electrode each includes a source electrode and a drain electrode.

9. An array substrate, comprising the complementary TFT according to claim 8.

10. An array substrate according to claim 9, further comprising in turn:
a base substrate; the gate electrode of the N-type metal oxide TFT and the gate electrode of the P-type metal oxide TFT being arranged on the base substrate;
a gate insulation layer arranged between the gate electrodes of both the N-type and P-type metal oxide TFTs and the active layers of both the N-type and P-type metal oxide TFTs;
a pattern of a first etch stop layer between the active layer of the N-type metal oxide TFT and the source/drain electrodes of the N-type metal oxide TFT and a pattern of a second etch stop layer between the active layer of the P-type metal oxide TFT and the source/drain electrodes of the P-type metal oxide TFT; and
a passivation layer covering the source electrode and the drain electrode of the N-type metal oxide TFT and the source electrode and the drain electrode of the P-type metal oxide TFT.

11. The array substrate according to claim 9, further comprising in turn:
a base substrate, the active layer of the N-type metal oxide TFT and the active layer of the P-type metal oxide TFT being arranged on the base substrate;
a pattern of a first etch stop layer between the active layer of the N-type metal oxide TFT and the source/drain electrodes of the N-type metal oxide TFT, and a pattern of a second etch stop layer between the active layer of the P-type metal oxide TFT and the source/drain electrodes of the P-type metal oxide TFT;
a gate insulation layer, the gate electrode of the N-type metal oxide TFT and the gate electrode of the P-type metal oxide TFT being arranged on the gate insulation layer; and
a passivation layer covering the gate electrode of the N-type metal oxide TFT and the gate electrode of the P-type metal oxide TFT.

12. The array substrate according to claim 9, wherein the source electrode and the drain electrode of the N-type metal oxide TFT and the source electrode and the drain electrode of the P-type metal oxide TFT are each made of Al or Mo, or an alloy thereof.

13. The array substrate according to claim 9, further comprising in turn:
a base substrate, the gate electrode of the N-type metal oxide TFT and the gate electrode of the P-type metal oxide TFT being arranged on the base substrate;
a gate insulation layer, the active layer of the N-type metal oxide TFT and the active layer of the P-type metal oxide TFT being arranged on the gate insulation layer; and
a passivation layer covering the source electrode and the drain electrode of the N-type metal oxide TFT and the source electrode and the drain electrode of the P-type metal oxide TFT.

14. The array substrate according to claim 9, further comprising in turn:
a base substrate, the active layer of the N-type metal oxide TFT and the active layer of the P-type metal oxide TFT being arranged on the base substrate;
a gate insulation layer arranged between the source/drain electrodes of both the N-type and P-type metal oxide TFTs and the gate electrodes of both the N-type and P-type metal oxide TFTs; and
a passivation layer covering the gate electrode of the N-type metal oxide TFT and the gate electrode of the P-type metal oxide TFT.

15. The array substrate according to claim 13, wherein the source electrode and the drain electrode of the N-type metal oxide TFT and the source electrode and the drain electrode of the P-type metal oxide TFT are each made of Cu.

16. The array substrate according to claim 14, wherein the source electrode and the drain electrode of the N-type metal oxide TFT and the source electrode and the drain electrode of the P-type metal oxide TFT are each made of Cu.

17. A display device comprising the array substrate according to claim 9.
